(19) United States
(12) Patent Application Publication
(10) Pub. No.: US 2004/0076048 A1
(43) Pub. Date: Apr. 22, 2004

(54) Universal serial bus flash bay

(75) Inventors: Greg V. Kabenjian, Austin, TX (US); Kenneth J. Haugen, Dakota Dunes, SD (US); Toby R. Baird, Pleasanton, CA (US)

Correspondence Address: GATEWAY, INC., ATTN: SCOTT CHARLES RICHARDSON, 610 GATEWAY DRIVE, MAIL DROP Y-04, NORTH SIOUX CITY, SD, 57049, US

(73) Assignee: Spotware Technologies, Inc.

(21) Appl. No.: 10/664,388

(22) Filed: Sep. 17, 2003

Related U.S. Application Data
(60) Provisional application No. 60/420,207, filed on Oct. 22, 2002.

(51) Int. Cl. G11C 29/00

(52) U.S. Cl. 365/200

(57) ABSTRACT

A universal serial bus flash bay apparatus for integrating in an external drive bay of an information handling system assembly includes a universal serial bus port, flash card slot, universal serial bus hub and flash card reader controller. The universal serial bus is interfaced with the flash card reader controller. The universal serial bus flash bay is capable of connecting with a communication and networking riser disposed within the information handling system assembly.

### FIELD OF THE INVENTION

The present invention generally relates to the field of universal interface technology such as universal serial bus hubs and ports, and flash card reader controllers and slots, and particularly to a universal serial bus flash bay apparatus for integrating and combining universal serial bus ports and flash card slots in an external drive bay of an information handling system assembly.

### BACKGROUND OF THE INVENTION

Generally, universal interface technology focuses on data transfer capabilities. One capability is the universal serial bus (USB) interface and a second is the flash media interface. It may be common for an information handling system assembly to include at least one USB port within its housing separate from external drive bays, however, flash media devices and multiple USB port capabilities have generally been contained in peripheral devices interfaced with a host. Even though these devices have generally been of modest physical dimensions they still occupy workstation and storage space. Both these interface mediums provide numerous advantages such as ease of operator use of compatible devices, the ability to network additional memory, provide a wider range of application capabilities, and the like.

Typically, peripheral devices work well at a desktop location of an information handling system assembly with an abundance of available free space. However, operators wish to connect these devices, containing either multiple USB ports or flash media, to an information handling system assembly, which has limited free space, such as a portable information handling system assembly (e.g., laptop computer and the like) where available free space is at a premium. For instance, use of a laptop in an airplane or automobile wherein an operator's free space may be confined to their lap makes the use of peripheral devices difficult. Having to store and carry these peripheral devices along with the information handling system assembly, when the operator is on the go, places an additional burden on the operator.

Therefore, it would be desirable to provide a USB flash bay apparatus capable of integrating and combining USB ports and flash card slots for insertion in an external drive bay of an information handling system assembly, wherein the USB flash bay apparatus may be inserted in external drive bays, such as but not limited to a standard three and one-half inch external drive bay or a five and one-quarter inch external drive bay of an information handling system assembly.

### SUMMARY OF THE INVENTION

Accordingly, the present invention is directed to a USB flash bay, which can be integrated with an information handling system assembly. The USB flash bay is suitable for being inserted in an external drive bay of an information handling system assembly. The USB flash bay includes at least one USB port, at least one flash card slot, at least one USB hub and at least one flash card reader controller, and is capable of interfacing with the information handling system assembly in which it is placed.

The USB flash bay provides an operator of the information handling system assembly a simple, space efficient, storage conscious, low-cost way for interfacing multiple USB ports and flash card slots which are capable of communicatively coupling the information handling system assembly with a wide variety of portable application and storage devices (e.g., compact flash, SmartMedia, Secure Digital, MultiMedia Card, Memory Stick, and the like).

An operator of an information handling system assembly may have been forced to utilize two peripheral devices in order to support USB ports and flash card media. The USB flash bay provides such operators the ability to integrate such capabilities within their existing system without adding significant peripheral hardware and cost. This makes the use of USB ports and flash card slots easier by removing any storage or space considerations that peripheral devices inherently have.

It is to be understood that both the forgoing general description and the following detailed description are exemplary and explanatory only and are not restrictive of the invention as claimed. The accompanying drawings, which are incorporated in and constitute a part of the specification, illustrate an embodiment of the invention and together with the general description serve to explain the principles of the invention.

### BRIEF DESCRIPTION OF THE DRAWINGS

The numerous advantages of the present invention may be better understood by those skilled in the art by reference to the accompanying figures in which:

FIG. 1 is an isometric view illustrating a USB flash bay in accordance with an exemplary embodiment of the present invention;

FIG. 2 is a logical diagram illustrating the USB flash bay card in accordance with an exemplary embodiment of the present invention;

FIG. 3A is an isometric view illustrating a USB flash bay disposed within an information handling system assembly in accordance with an exemplary embodiment of the present invention;

FIG. 3B is a cutaway internal view of the information handling system assembly illustrating the connection of the USB flash bay with a communication and networking riser disposed within the information handling system assembly;

FIG. 4A is an isometric view illustrating a modular USB flash bay in accordance with an exemplary embodiment of the present invention; and

FIG. 4B is an isometric view illustrating the modular USB flash bay being capable of insertion and removal from the housing of an information handling system assembly.

### DETAILED DESCRIPTION OF THE INVENTION

Reference will now be made in detail to the presently preferred embodiments of the invention, examples of which are illustrated in the accompanying drawings.

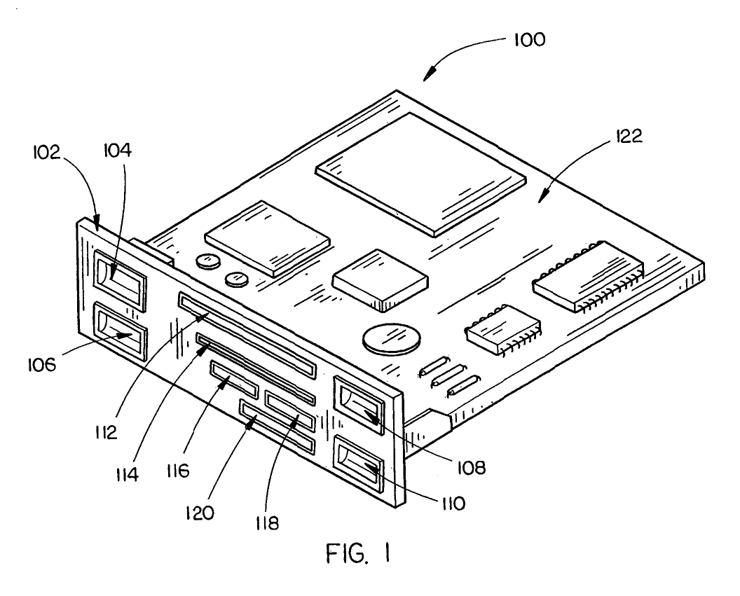

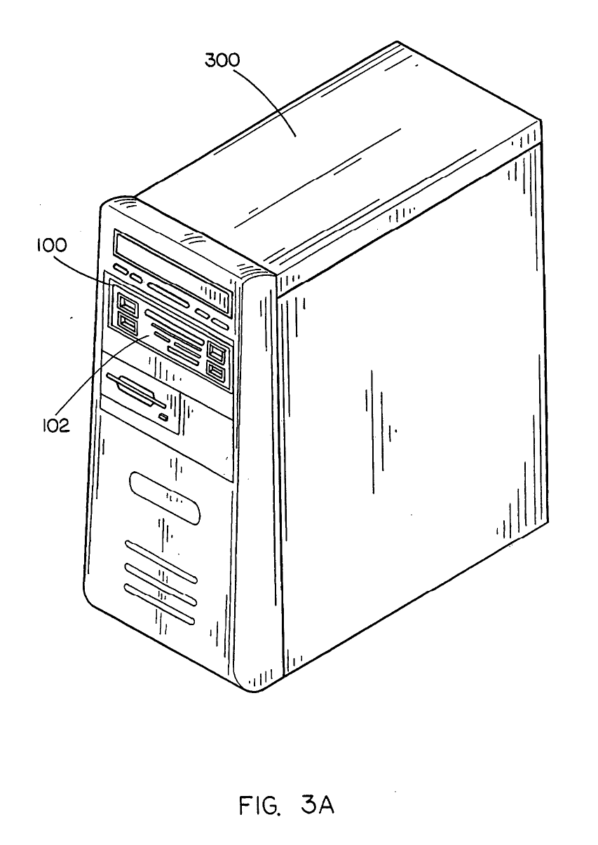

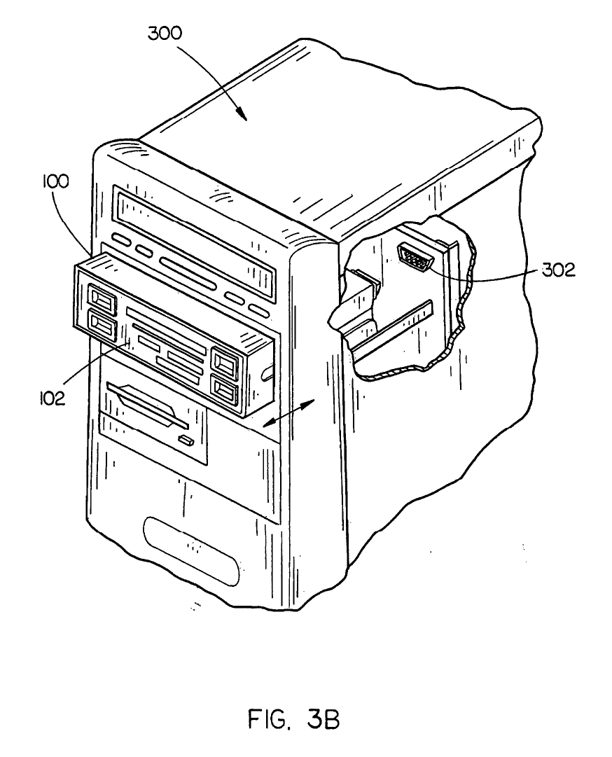

Referring now to FIG. 1, a USB flash bay 100 in accordance with an exemplary embodiment of the present invention is described. Preferably, USB flash bay 100 has specific dimensions, which allow it to occupy the area of a standard three and one-half inch external drive bay. Alternatively, the USB flash bay 100 can be given dimensions that would allow it to occupy other areas such as a five and one-fourth inch external drive bay, and the like. It is contemplated that USB flash bay 100 may be integrated with a variety of information handling system assemblies, such as the information handling system assembly shown in FIG. 3.

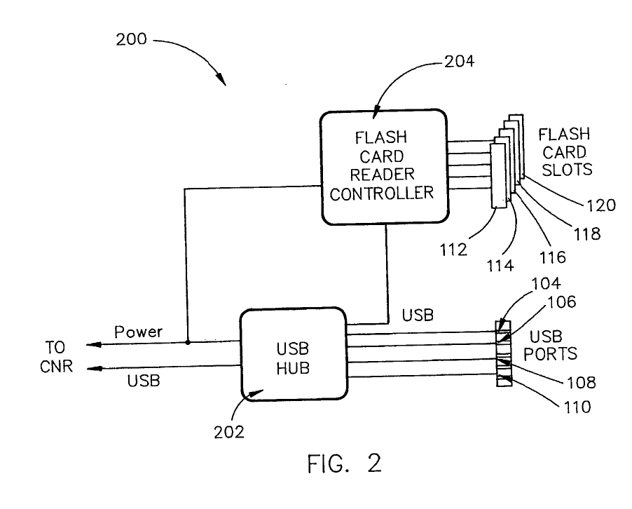

USB flash bay 100 includes a faceplate 102 for interfacing with universal interface technology mediums and a card 122 for interfacing with a host system such as an information handling system. Card 122 is described in the logical diagram of FIG. 2 below. Preferably, the faceplate 102 includes four universal serial bus (USB) ports and five flash card slots/ports. However, the faceplate 102 may include any number of USB ports and flash card slots. For instance, the faceplate 102 may include a single USB port and a single flash slot. In the present embodiment two of the universal serial bus ports 104 and 106 are disposed along one side of faceplate 102 while the other two universal serial bus ports 108 and 110 are disposed along the opposite side of faceplate 102. The flash media card slots are disposed substantially in the center of faceplate 102 between the two groupings of universal serial bus ports. A first flash card slot 112 is located near the top of faceplate 102 and is identified for enabling Compact Flash (CF) media and immediately below CF slot 112 is a second flash card slot 114 which is identified for enabling SmartMedia (SM) media. Immediately below SM slot 114 are third and fourth flash card slots 116 and 118, which are adjacent to one another. Third flash card slot 116 is identified for enabling Secure Digital (SD) media and fourth flash card slot 118 is identified for enabling MultiMedia Cards (MMC). A fifth flash card slot 120 is located immediately below SD slot 116 and MMC slot 118. Slot 120 is identified for enabling Memory Stick (MS) media.

It is contemplated that the physical location of the ports and slots on faceplate 102 may be varied from the exemplary embodiment by one of ordinary skill in the art. For instance, all four universal serial bus ports may be grouped together on one side of faceplate 102 with the five flash card slots located opposite. Further, faceplate 102 can be designed with multiple architectures, from designs which encompass any number of interface points for only one medium (either USB or Flash Card) to designs that allow any combination of these interface mediums. Thus, operators are be given the opportunity to choose designs which best fit their needs and have the universal interface technology integrated within their system (i.e. information handling system assembly) and not occupy any additional space.

Generally, the USB flash bay is capable of supporting over one hundred and twenty seven devices, from a network connection to global positioning systems, to barcode scanners, and the like. The flash card slots and flash card reader controller are capable of supporting and reading devices that have a flash card mechanical format and interface. For example, MicroOptical Drives and Cards, other removable media, and the like. Such a variety of capacity will appeal to consumers looking to simplify their computing experience by combining multiple functions into one location.

The present invention may support adding or replacing some of faceplate 102 slots and ports with other data transfer options, thereby increasing utility of the host system. Data transfer options such as, serial ports, IEEE 1394 ports (firewire), Bluetooth, IrDA (infrared) ports and card slots for devices such as the MicroOptical, and other removable media, as mentioned above, are contemplated.

Referring now to FIG. 2, a logical diagram 200 of the USB flash bay card 122 is illustrated in this exemplary embodiment. Logical diagram 200 includes a USB hub 202 and a flash card reader controller 204. In the embodiment shown USB hub 202 functions as a USB 2.0 hub, not as a USB 2.0 controller. USB hub 202 interfaces four upstream Series “A” USB connectors and two downstream Series “B” USB connectors. It is contemplated that USB hub 202 can interface from one to a plurality of upstream Series “A” and downstream Series “B” USB connectors.

Flash card reader controller 204 supports five upstream connectors, which are Compact Flash, SmartMedia, Secure Digital, MultiMedia Card and Memory Stick slots, described in FIG. 1. Further, flash card reader controller 204 is capable of reading a variety of other devices that have a flash card mechanical format and interface. Flash card reader controller 204 has two downstream connectors, one is for connecting a power source and the other is a USB 2.0 interface for connecting it with USB hub 202. Flash card reader controller 204 enumerates as a standard USB mass storage device, and does not require a driver to read supported media.

Flash card reader controller 204 and USB Hub 202 are supplied power and utilize USB signals from a communication and networking riser (CNR) connector, disposed within a host system (i.e. information handling system assembly). An insert card placed in the CNR connector provides stake pins for a cable leading to the USB flash bay. The USB flash bay may utilize a power source separate from the host system to which it is attached, either an external source or one that is disposed within the USB flash bay itself.

Different internal system architecture can be implemented within USB flash bay card 122 without departing from the scope and spirit of the present invention. For example, a USB Hub capable of supporting different USB versions such as USB 1.0 and USB 1.1 or even the USB CDC Version 1.1. As discussed in the description of FIG. 1 USB flash bay 100 may include a MicroOptical Drive and other removable media. Other possible supportable data transfer options include serial ports with differing pin connection adapters, IEEE 1394, Bluetooth and IrDA. Each of these options may include a controller and/or hub mechanism within the USB flash bay to function properly.

Referring to FIGS. 3A and 3B, an information handling system assembly 300 having a USB flash bay 100 in accordance with an exemplary embodiment of the present invention is described. Information handling system assembly 300 is a desk top personal computer (PC). The PC includes a standard three and one-half inch external drive bay. As shown, faceplate 102 of USB flash bay 100 occupies the three and one-half inch external drive bay. In this configuration USB flash bay 100 is flush with the housing of information handling system assembly 300 thereby conserving space.

USB flash bay 100 is connected with communication and networking riser (CNR) slot 302. This coupling provides power to USB flash bay 100 and also connects it to the universal serial bus included within information handling system assembly 300. The coupling occurs through the use of a CNR connector in which an insert card is placed, for providing the stake pins for a cable leading to USB flash bay 100. Other power and universal serial bus connections may be contemplated by one or ordinary skill in the art without departing from the scope and spirit of the present invention.

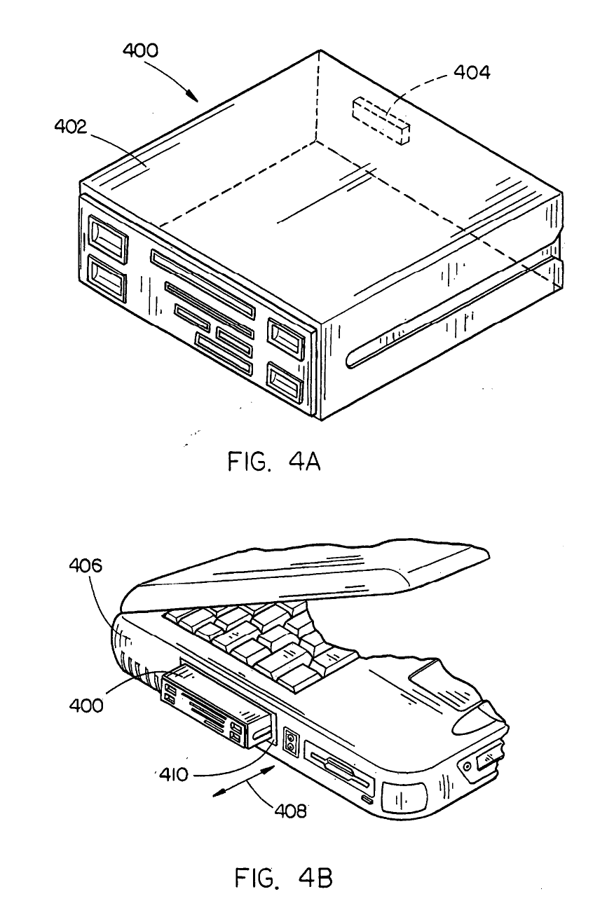

Referring to FIGS. 4A and 4B, an exemplary modular USB flash bay 400 is shown. USB flash bay 400 includes similar features and capabilities as described by FIGS. 1 and 2. In the present embodiment, however, the circuitry and faceplate is contained within an enclosure 402. Enclosure 402 is of appropriate physical dimensions to allow it to integrate within a standard three and one-half inch external drive bay. Enclosure 402 includes an adapter port 404, which enables USB flash bay 400 to connect with an information handling system assembly capable of integrating such a modular system. Enclosure 402 enables a portable means of providing universal interface technology and it is contemplated that USB flash bay 400 may be integrated with a variety of information handling system assemblies. Further, with the physical dimensions mentioned above, USB flash bay 400 would store easily, making its use convenient even in a limited space environment.

Enclosure 402 provides protection for USB flash bay 400 from physical and environmental damage. For instance, dust and water are kept out of the circuitry and stresses from being swapped in and out of a variety of information handling system assemblies are minimized. The materials that comprise enclosure 402 may include plastic, steel, aluminum and the like. The use of steel, and materials like it, provide an electromagnetic interface shield protecting the circuitry from such harmful interference. Additionally, use of very tactile magnesium may enable enclosure 402 to assist in dampening vibration transfer to the internal circuitry.

Insertion and removal capabilities from a housing 406, such as an information handling system assembly, is represented by the dual directional arrow 408. This movement is accomplished through physical exertion on the part of a user. The user will position USB flash bay 400 in front of the modular component slot 410 included in housing 406. Then by firmly applying pressure the user inserts USB flash bay 400 within housing 406. The user keeps applying pressure until USB flash bay 400 is properly seated within modular component slot 410. A “locking” or “latching” mechanism may be included that engages and holds the component firmly in place upon the proper seating of the component within housing 406. Such proper seating ensures the user that USB flash bay 400 is properly engaged with housing 406. Proper engagement can be through connection of USB flash bay 400 with a CNR connector as mentioned previously or through some other means.

It is believed that the universal serial bus flash bay of the present invention and many of its attendant advantages will be understood by the foregoing description. It is also believed that it will be apparent that various changes may be made in the form, construction and arrangement of the components thereof without departing from the scope and spirit of the invention or without sacrificing all of its material advantages. The form herein before described being merely an explanatory embodiment thereof. It is the intention of the following claims to encompass and include such changes.

What is claimed is:

1. A USB flash bay for an information handling system, comprising:
a USB hub communicatively coupled with a USB port;
a flash card reader controller communicatively coupled with a flash card slot, the flash card reader controller interfacing with the USB hub; and
a faceplate including the USB port and the flash card slot,
wherein the USB flash bay is suitable for being integrated in a drive bay of the information handling system.

2. The USB flash bay of claim 1, wherein the USB flash bay is capable of integrating in at least one of a standard three and one-half inch external drive bay and a five and one-fourth inch external drive bay disposed within the information handling system.

3. The USB flash bay of claim 1, wherein the USB flash bay is capable of connecting to a peripheral power source and universal serial bus.

4. The USB flash bay of claim 1, wherein the USB flash bay is capable of connecting to a peripheral power source and universal serial bus by communicatively coupling with a communication and networking riser disposed within the information handling system assembly.

5. The USB flash bay of claim 1, wherein the USB flash bay houses a universal serial bus hub communicatively coupled with at least four USB ports.

6. The USB flash bay of claim 1, wherein the USB flash bay houses a flash card reader controller communicatively coupled with at least five flash card slots.

7. The USB flash bay of claim 1, wherein the USB flash bay is capable of being enclosed in a housing.

8. The USB flash bay of claim 1, wherein the USB flash bay is enclosed in a housing including a connector port adapter suitable for connecting with a variety of information handling systems.

9. A drive bay assembly, comprising:
an external drive bay disposed within an information handling system;
a USB flash bay including a USB hub and a flash card reader controller interfacing with the USB hub; and
a faceplate disposed upon the USB flash bay, the faceplate including a USB port communicatively coupled to the USB hub and a flash card slot communicatively coupled to the flash card reader controller,
wherein the USB flash bay is suitable for being integrated in the external drive bay of the information handling system.

10. The drive bay assembly of claim 9, wherein the USB flash bay is capable of integrating in at least one of a standard three and one-half inch external drive bay and a five and one-fourth inch external drive bay disposed within the information handling system.

11. The drive bay assembly of claim 9, wherein the USB flash bay is capable of connecting to a peripheral power source and universal serial bus.

12. The drive bay assembly of claim 9, wherein the USB flash bay is capable of connecting to a peripheral power source and universal serial bus by communicatively coupling with a communication and networking riser disposed within the information handling system assembly.

13. The drive bay assembly of claim 9, wherein the USB flash bay houses a USB hub communicatively coupled with at least four USB ports.

14. The drive bay assembly of claim 9, wherein the USB flash bay houses a flash card reader controller communicatively coupled with at least five flash card slots.

15. The drive bay assembly of claim 9, wherein the USB flash bay is capable of being enclosed in a housing.

16. The drive bay assembly of claim 9, wherein the USB flash bay is enclosed in a housing including a connector port adapter suitable for connecting with a variety of information handling systems.

17. An information handling system, comprising:
an enclosure;
an external drive bay disposed within the enclosure;
a USB flash bay including a USB hub and a flash card reader controller interfacing with the USB hub; and
a faceplate disposed upon the USB flash bay, the faceplate including a USB port communicatively coupled to the USB hub and a flash card slot communicatively coupled to the flash card reader controller,
wherein the USB flash bay is suitable for being integrated in the external drive bay of the enclosure.

18. The information handling system of claim 17, wherein the USB flash bay is capable of integrating in at least one of a standard three and one-half inch external drive bay and a five and one-fourth inch external drive bay disposed within the enclosure.

19. The information handling system of claim 17, wherein the USB flash bay is capable of connecting to a peripheral power source and universal serial bus.

20. The information handling system of claim 17, wherein the USB flash bay is capable of connecting to a peripheral power source and universal serial bus by communicatively coupling with a communication and networking riser disposed within the information handling system assembly.

21. The information handling system of claim 17, wherein the USB flash bay houses a USB hub communicatively coupled with at least four USB ports.

22. The information handling system of claim 17, wherein the USB flash bay houses a flash card reader controller communicatively coupled with at least five flash card slots.

23. The information handling system of claim 17, wherein the USB flash bay is capable of being enclosed in a housing.

24. The information handling system of claim 17, wherein the USB flash bay is enclosed in a housing including a connector port adapter suitable for connecting with a variety of information handling systems.

25. A USB flash bay for an information handling system, comprising:
means for an external drive bay disposed within the information handling system;
means for a USB flash bay including a USB port and a flash card slot;
means for integrating the USB flash bay in the external drive bay; and
means for connecting the USB flash bay with the information handling system.

26. The USB flash bay of claim 25, wherein the external drive bay is at least one of a standard three and one-half inch external drive bay and a five and one-fourth inch external drive bay.

27. The USB flash bay of claim 25, wherein the means for a USB flash bay is a faceplate containing the USB port and the flash card slot, wherein a USB hub is communicatively coupled with the USB port and interfaced with a flash card reader controller which is communicatively coupled with the flash card slot.

28. The USB flash bay of claim 25, wherein the integrating means includes physically locating the USB flash bay within the external drive bay

29. The USB flash bay of claim 25, wherein the connecting means is through a communicative coupling of the USB flash bay with a communication and networking riser slot disposed within the information handling system, which is capable of providing power and a connection with the universal serial bus of the information handling system..

30. The information handling system of claim 25, wherein the USB flash bay is capable of being enclosed in a housing.

31. The information handling system of claim 25, wherein the USB flash bay is enclosed in a housing including a connector port adapter suitable for connecting with a variety of information handling systems.
